(19) United States
(12) Patent Application Publication
(10) Pub. No.: US 2026/0106118 A1
(43) Pub. Date: Apr. 16, 2026

(54) SUBSTRATE TREATING APPARATUS

(71) Applicant: Samsung Electronics Co., Ltd., Suwon-si (KR)

(72) Inventors: Min Joon Kim, Suwon-si (KR); Dong Gyun Park, Suwon-si (KR); Bum-Soo Kim, Suwon-si (KR); Chang Hyeon An, Suwon-si (KR); Hyu Sung Jeon, Suwon-si (KR); Dea Woong Han, Suwon-si (KR)

(73) Assignee: Samsung Electronics Co., Ltd., Suwon-si (KR)

(21) Appl. No.: 19/347,939

(22) Filed: Oct. 2, 2025

(30) Foreign Application Priority Data
Oct. 16, 2024 (KR) 10-2024-0141370
Mar. 6, 2025 (KR) 10-2025-0029017

(51) Int. Cl. H01J 37/32

(52) U.S. Cl. CPC H01J 37/32541; H01J 37/32633; H01J 37/32642

(57) ABSTRACT

A substrate treating apparatus is provided. A substrate treating apparatus comprising a chuck supporting a substrate; an edge ring surrounding the chuck; a focus ring positioned on the edge ring; a cover ring surrounding the edge ring and the focus ring; a plasma baffle surrounding a side surface of the cover ring; a first ground ring in contact with a lower surface of the cover ring; and a second ground ring electrically connected to the first ground ring and in contact with the plasma baffle, wherein an upper surface of the first ground ring is placed at a level lower than that of an upper surface of the second ground ring.

### CROSS-REFERENCE TO RELATED APPLICATION

This present application claims priority to and the benefit under 35 U.S.C. 119(a)-(d) of Korean Patent Application No. 10-2024-0141370 filed on October 16th, 2024 and Korean Patent Application No. 10-2025-0029017 filed on March 6th, 2025 in the Korean Intellectual Property Office, the entire disclosure of which is incorporated herein by reference.

### FIELD

The present disclosure relates to a substrate treating apparatus.

### BACKGROUND

A semiconductor device may be fabricated through various processes such as, for example, a photolithography process, an etching process, and a deposition process on a wafer, for example, a silicon wafer. In these processes, various fluids may be used. For example, plasma may be used in the etching process and/or the deposition process. During the etching process and/or the deposition process, it may be necessary to control the position of the plasma. For this purpose, a focus ring or the like may be used.

### SUMMARY

One objective of the present disclosure is to provide a substrate treating apparatus with improved productivity.

The objectives of the present disclosure are not limited to those mentioned above, and other objectives not explicitly stated will be clearly understood by those skilled in the art based on the following description.

According to aspects of the present disclosure, there is provided a substrate treating apparatus comprising a chuck supporting a substrate; an edge ring surrounding the chuck; a focus ring positioned on the edge ring; a cover ring surrounding the edge ring and the focus ring; a plasma baffle surrounding a side surface of the cover ring; a first ground ring in contact with a lower surface of the cover ring; and a second ground ring electrically connected to the first ground ring and in contact with the plasma baffle, wherein an upper surface of the first ground ring is placed at a level lower than that of an upper surface of the second ground ring.

According to embodiments of the present disclosure, a substrate treating apparatus comprising a chuck supporting a substrate; an edge ring surrounding the chuck; a focus ring positioned on the edge ring; a cover ring surrounding the edge ring and the focus ring; a plasma baffle surrounding the cover ring; a first ground ring in contact with the cover ring; and a second ground ring surrounding the cover ring, wherein at least a portion of the first ground ring is surrounded by the cover ring.

According to embodiments of the present disclosure, a substrate treating apparatus comprising a chuck supporting a substrate; an edge ring surrounding the chuck; a focus ring positioned on the edge ring; a cover ring surrounding the edge ring and the focus ring; an insulation ring positioned between the edge ring and the cover ring; a plasma baffle surrounding a side surface of the cover ring; a first ground ring in contact with a lower surface of the cover ring and connected to ground; and a second ground ring electrically connected to the first ground ring and in contact with the plasma baffle, wherein an upper surface of the first ground ring is positioned at a lower level than that of an upper surface of the second ground ring, a plasma region, into which plasma penetrates from a process space defined by the plasma baffle, is further provided between the cover ring and the plasma baffle and between the cover ring and the second ground ring, and the first ground ring is positioned at a lower level than that of the plasma region.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a cross-sectional view illustrating a substrate treating apparatus according to some embodiments of the present disclosure.

FIG. 2 is an enlarged cross-sectional view of region X in FIG. 1.

FIG. 3 is a perspective view of a first ground ring according to embodiments of the present disclosure.

FIG. 4 is an enlarged cross-sectional view of region X in FIG. 1.

FIG. 5 is an enlarged cross-sectional view of region X in FIG. 1.

FIG. 6 is an enlarged cross-sectional view of region Y in FIG. 5.

FIG. 7 is a cross-sectional view illustrating a substrate treating apparatus according to some embodiments of the present disclosure.

FIG. 8 is an enlarged cross-sectional view of region Z in FIG. 7.

FIG. 9 is an enlarged cross-sectional view of region W in FIG. 8.

FIG. 10 is a perspective view of a first ground ring according to embodiments of the present disclosure.

FIG. 11 is an enlarged cross-sectional view of region Z in FIG. 7.

FIG. 12 is an enlarged cross-sectional view of region Z in FIG. 7.

FIG. 13 is an enlarged cross-sectional view of region W in FIG. 12.

### DETAILED DESCRIPTION

Embodiments of the present disclosure will hereinafter be described in detail with reference to the accompanying drawings. In the drawings, the same reference numerals are used for the same components, and repeated descriptions thereof will be omitted.

In the following description, D1 denotes a first direction, D2 denotes a second direction intersecting the first direction D1, and D3 denotes a third direction intersecting both the first and second directions D1 and D2. The first direction D1 may also be referred to as a vertical direction, and the second and third directions D2 and D3 may each be referred to as a horizontal direction.

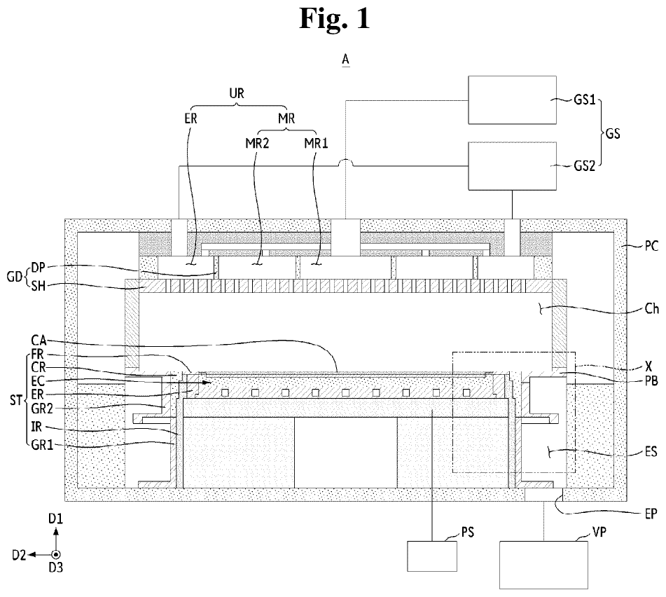

FIG. 1 is a cross-sectional view illustrating a substrate treating apparatus according to some embodiments of the present disclosure.

Referring to FIG. 1, a substrate treating apparatus A may be provided. The substrate treating apparatus A may refer to an apparatus that treats a substrate using plasma. The substrate may include, for example, a silicon (Si) wafer, but is not limited thereto. The substrate treating apparatus A may perform an etching process and/or a deposition process on the substrate using plasma. For example, the substrate treating apparatus A may perform a Bosch process that repeatedly performs etching and deposition on the substrate using plasma.

The substrate treating apparatus A may generate plasma in various manners. For example, the substrate treating apparatus A may generate plasma using a method such as capacitor coupled plasma (CCP), inductively coupled plasma (ICP), or magnetically enhanced reactive ion etching (MERIE), but is not limited thereto. That is, the substrate treating apparatus A may generate plasma using other methods and perform processing on the substrate. For convenience, the substrate treating apparatus A will hereinafter be described as using the CCP method.

The substrate treating apparatus A may include a process chamber PC, a gas supply unit GS, a gas distribution unit GD, a stage ST, a plasma baffle PB, a vacuum pump VP, and a power source PS.

The process chamber PC may provide a process space Ch. The process chamber PC may be connected to the gas supply unit GS and receive process gas from the gas supply unit GS. The process gas may include, for example, hydrogen (H₂). The process chamber PC may be connected to the vacuum pump VP. Fluids such as the process gas in the process space Ch may be discharged toward the vacuum pump VP. The process chamber PC may provide an exhaust port EP. The process space Ch may be connected to the vacuum pump VP through the exhaust port EP. The exhaust port EP may be offset to one side of the process chamber PC. For example, as illustrated in FIG. 1, the exhaust port EP may be offset to the right side of the process chamber PC. The stage ST and the plasma baffle PB may be provided inside the process chamber PC.

The gas supply unit GS may supply process gas to the process space Ch. To this end, the gas supply unit GS may include a gas tank, a compressor, pipes, and a control unit. The gas supply unit GS may supply various types of gases. To this end, the gas supply unit GS may include a first gas supply unit GS1 and a second gas supply unit GS2. The first gas supply unit GS1 may supply a first process gas. The first process gas may be supplied to the process space Ch so as to spread throughout the entire process space Ch. The second gas supply unit GS2 may supply a second process gas. The second process gas may include a different type of gas from the first process gas. The second process gas may be supplied to be biased toward one side of the process space Ch.

The gas distribution unit GD may be located in the process chamber PC. The gas distribution unit GD may distribute process gas into the process space Ch. To this end, the gas distribution unit GD may include a shower head SH and a gas dividing plate DP. The shower head SH may provide a plurality of gas supply holes. The shower head SH may function as an upper electrode. The shower head SH may separate a distribution space UR, which is a space above the shower head SH, from the process space Ch. The distribution space UR may be divided into an intermediate region MR and an edge region ER. For example, the gas dividing plate DP may divide the intermediate region MR and the edge region ER. The intermediate region MR may be divided into a first intermediate region MR1 and a second intermediate region MR2. The first process gas may be supplied to all of the first intermediate region MR1, the second intermediate region MR2, and the edge region ER. The second process gas may be supplied only to the edge region ER. The process gas supplied into the distribution space UR may be distributed through the gas supply holes of the shower head SH and move into the process space Ch.

The stage ST may support a substrate. The stage ST may be located in the process chamber PC. The stage ST may include a chuck EC, a focus ring FR, an edge ring ER, an insulation ring IR, a cover ring CR, a first ground ring GR1, and a second ground ring GR2. The stage ST will be described later in further detail.

The plasma baffle PB may surround the stage ST. For example, the plasma baffle PB may surround the stage ST at a height similar to that of the focus ring FR, but is not limited thereto. Alternatively, the plasma baffle PB may surround the stage ST below the chuck EC. Yet alternatively, the plasma baffle PB may be positioned higher than the focus ring FR. The space below the plasma baffle PB may be referred to as an exhaust space ES. The exhaust space ES may be connected to the exhaust port EP. The plasma baffle PB may direct the gas in the process space Ch toward the exhaust space ES. That is, the gas in the process space Ch may be discharged to the exhaust port EP, passing through the plasma baffle PB and then through the exhaust space ES. Plasma may have relatively poor permeability through the plasma baffle PB. That is, the plasma baffle PB may restrict the location of the plasma. Due to the presence of the plasma baffle PB, the plasma may be concentrated on the substrate placed on the stage ST. Therefore, the plasma baffle PB may also be referred to as a confinement ring. The plasma baffle PB may be fixed to the stage ST and/or the process chamber PC. For example, the plasma baffle PB may be fixed to the process chamber PC by bolts (not illustrated).

The vacuum pump VP may be connected to the process chamber PC. Specifically, the vacuum pump VP may be connected to the process space Ch through the exhaust port EP. The vacuum pump VP may draw in fluid from the process space Ch. The vacuum pump VP may be located on a lower side of the process chamber PC, but is not limited thereto. Alternatively, the vacuum pump VP may be located beside the process chamber PC.

The power source PS may be electrically connected to the chuck EC. The power source PS may apply power to the chuck EC. For example, the power source PS may apply radio frequency (RF) power to the chuck EC. To this end, the power source PS may include components capable of generating and delivering RF power. The power source PS will be described later in further detail.

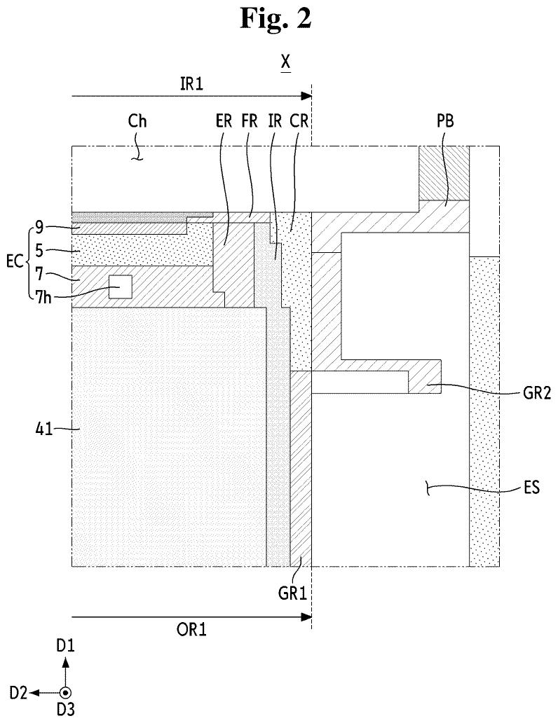

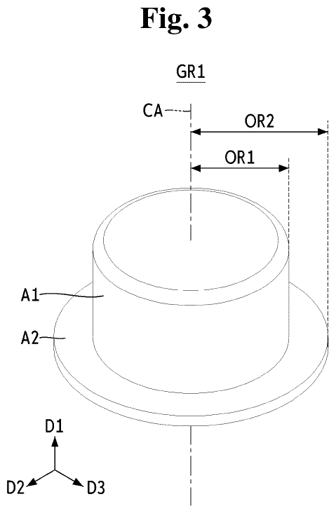

FIG. 2 is an enlarged cross-sectional view of region X in FIG. 1. FIG. 3 is a perspective view of a first ground ring according to embodiments of the present disclosure.

Referring to FIGS. 2 and 3, the stage ST may include the chuck EC, the focus ring FR, the edge ring ER, the insulation ring IR, the cover ring CR, the first ground ring GR1, and the second ground ring GR2.

The chuck EC may support a substrate. The chuck EC may fix the substrate at a predetermined position using electrostatic force. That is, the chuck EC may be an electrostatic chuck (ESC). The chuck EC may have a columnar shape centered on a chuck center CA, but is not limited thereto.

The chuck EC may include a puck 5, a plasma electrode 9, a cooling plate 7, and a chuck electrode.

The puck 5 may support the substrate. A burl structure configured to support the substrate may be provided on the upper surface of the puck 5. The puck 5 may include ceramic, but is not limited thereto. Also, a heater may be provided inside the puck 5.

The plasma electrode 9 may be located inside the puck 5. The plasma electrode 9 may be connected to the power source PS of FIG. 1. An electric field may be generated in the process space Ch by power supplied from the power source PS to the plasma electrode 9. To this end, the plasma electrode 9 may include a conductive material.

The cooling plate 7 may be located below the puck 5. The cooling plate 7 may include a material having high thermal conductivity. For example, the cooling plate 7 may include aluminum (Al). The cooling plate 7 may provide a cooling channel 7h. Cooling water may absorb heat while flowing through the cooling channel 7h.

The chuck electrode may be located inside the puck 5. Due to the presence of the chuck electrode, the substrate on the puck 5 may be fixed to the upper surface of the puck 5.

An insulation plate 41 may be located below the chuck EC. The insulation plate 41 may include an insulating material such as ceramic.

The focus ring FR may surround the chuck EC. Specifically, from a planar perspective, the focus ring FR may surround the substrate placed on the chuck EC. The focus ring FR may be located on the edge ring ER and the insulation ring IR. The focus ring FR may include an insulating material. For example, the focus ring FR may include an insulating material such as quartz.

The edge ring ER may surround the chuck EC. The edge ring ER may be located below the focus ring FR. The edge ring ER may include an insulating material. For example, the edge ring ER may include an insulating material such as quartz.

The insulation ring IR may surround the edge ring ER and the insulation plate 41. The insulation ring IR may be located below the focus ring FR. Also, an inner surface of the insulation ring IR may be in contact with the edge ring ER and the insulation plate 41. Further, an outer surface of the insulation ring IR may be in contact with the cover ring CR and the first ground ring GR1. The insulation ring IR may include an insulating material. For example, the insulation ring IR may include an insulating material such as quartz.

The cover ring CR may surround portions of the focus ring FR and the insulation ring IR. Also, the outer surface of the cover ring CR may be surrounded by the plasma baffle PB and the second ground ring GR2. The cover ring CR may include an insulating material such as quartz.

The first ground ring GR1 may be positioned below the cover ring CR. The first ground ring GR1 may include a first region A1 and a second region A2. The first region A1 may have a first outer diameter OR1 with respect to the chuck center CA. The second region A2 may have a second outer diameter OR2 with respect to the chuck center CA. The outer diameter of the first region A1 may be the same as the outer diameter of the cover ring CR. That is, the cover ring CR may have the first outer diameter OR1 with respect to the chuck center CA.

An upper surface of the first ground ring GR1 may be in contact with the cover ring CR. That is, the cover ring CR may extend from its upper surface to the upper surface of the first ground ring GR1.

The first ground ring GR1 may surround the insulation ring IR. The first ground ring GR1 may be grounded to the process chamber PC in FIG. 1. The first ground ring GR1 may include a conductive material such as A1.

The second ground ring GR2 may be located outside the cover ring CR. Specifically, from a planar perspective, the second ground ring GR2 may surround the outer surface of the cover ring CR. That is, an inner diameter IR1 of the second ground ring GR2 may be greater than or equal to the outer diameter OR1 of the cover ring CR. The second ground ring GR2 may be located outside the first ground ring GR1. Additionally, from a planar perspective, the second ground ring GR2 may surround a portion of the first ground ring GR1. That is, the inner diameter IR1 of the second ground ring GR2 may be greater than or equal to the first outer diameter OR1 of the first region A1 of the first ground ring GR1.

The plasma baffle PB may be located outside the cover ring CR. Specifically, from a planar perspective, the plasma baffle PB may surround a portion of the outer surface of the cover ring CR. Also, the plasma baffle PB may contact an upper surface GR2u of the second ground ring GR2. The plasma baffle PB may provide a slit PBs. Through the slit PBs, the process space Ch and the exhaust space ES may be connected.

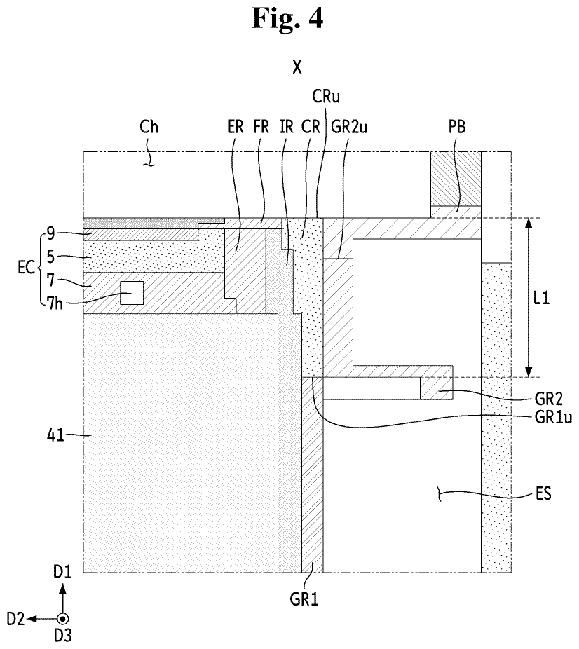

FIG. 4 is an enlarged cross-sectional view of region X in FIG. 1.

Referring to FIG. 4, the first ground ring GR1 may be positioned below the cover ring CR. Specifically, an upper surface GR1u of the first ground ring GR1 may be in contact with the cover ring CR. The distance between the upper surface GR1u of the first ground ring GR1 and an upper surface CRu of the cover ring CR may be a first distance L1. For example, the first distance L1 may be 20 mm or more.

In addition, the second ground ring GR2 may be arranged between the plasma baffle PB and the first ground ring GR1 to electrically connect the plasma baffle PB and the first ground ring GR1. That is, the plasma baffle PB may be grounded to the first ground ring GR1 through the second ground ring GR2. Specifically, an upper surface GR2u of the second ground ring GR2 may contact the plasma baffle PB and may be located at a higher level than the upper surface GR1u of the first ground ring GR1.

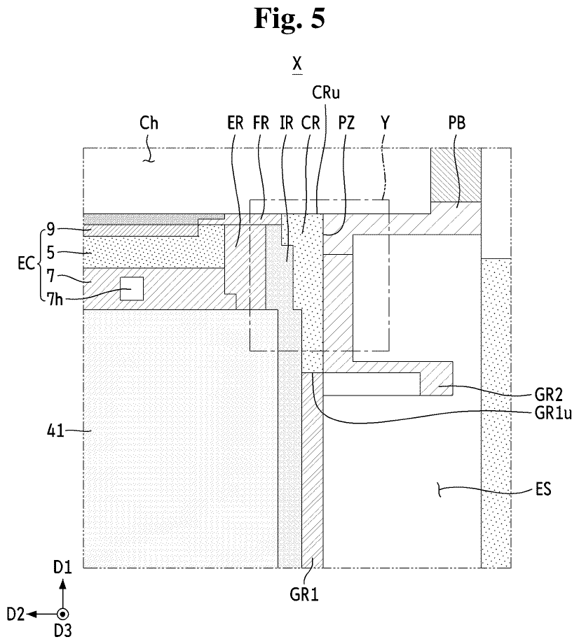

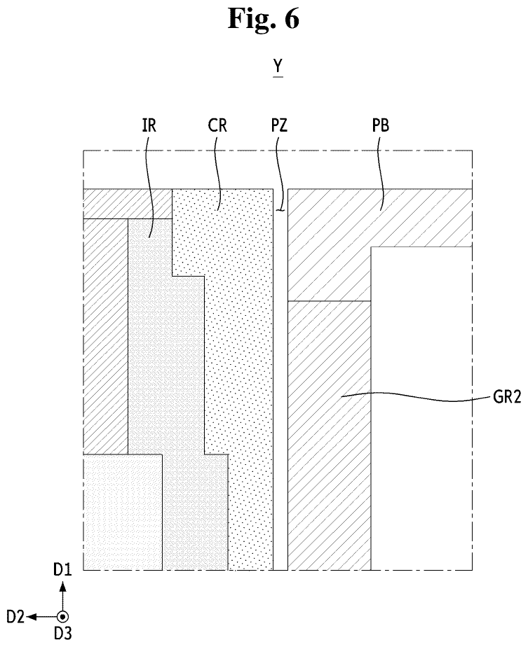

FIG. 5 is an enlarged cross-sectional view of region X in FIG. 1. FIG. 6 is an enlarged cross-sectional view of region Y in FIG. 5.

Referring to FIGS. 5 and 6, the substrate treating apparatus A may include a plasma region PZ between the cover ring CR and the plasma baffle PB, and between the cover ring CR and the second ground ring GR2. The plasma region PZ may refer to a region where plasma in the process space Ch penetrates and is detected.

In some embodiments, the first ground ring GR1 may be arranged at a lower level than the plasma region PZ. Accordingly, the first ground ring GR1 may not contact the plasma region PZ.

In embodiments, by including a cover ring CR having a length of 20 mm or more in the first direction D1, the first ground ring GR1 may not contact the plasma region PZ and thus may not be exposed to process gas. That is, peeling of the first ground ring GR1 by the process gas may be prevented. In addition, by preventing the peeling of the first ground ring GR1, it is possible to prevent the material peeled from the first ground ring GR1 (that may include, for example, A1) from reacting with process by-products to form other by-products (for example, AIF), which may fall onto the substrate being processed. Through this, a substrate treating apparatus with improved productivity may be provided.

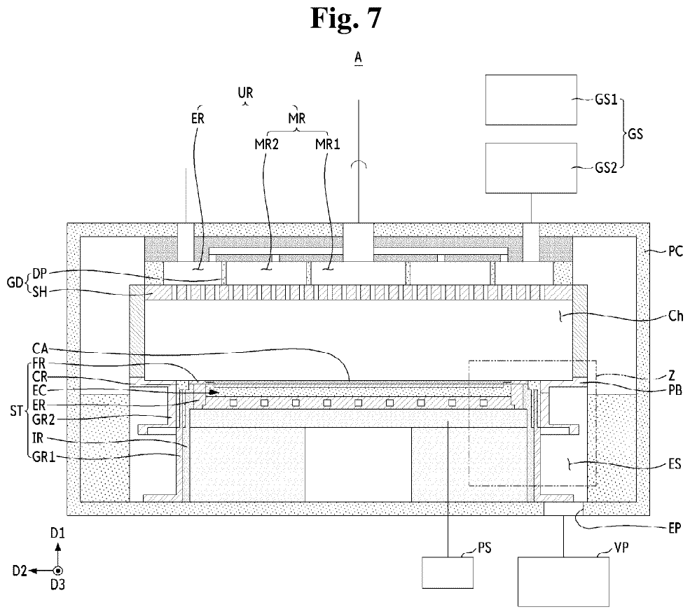

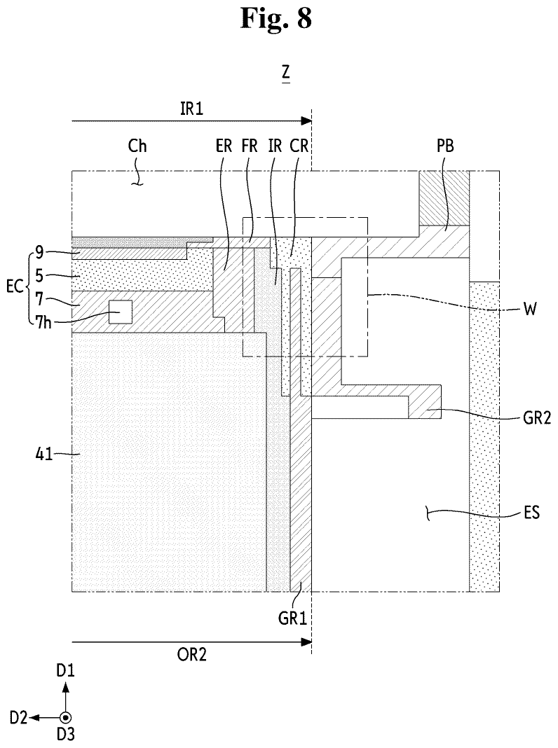

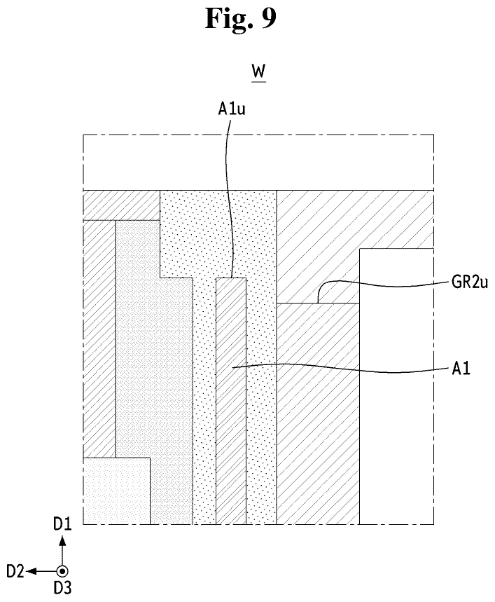

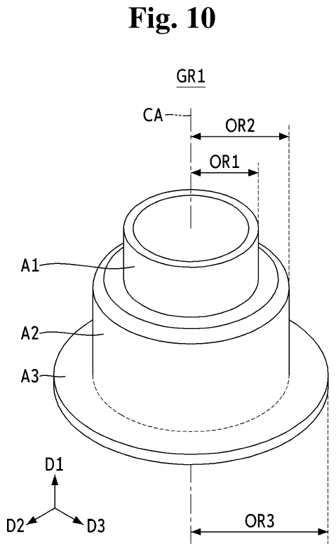

FIG. 7 is a cross-sectional view illustrating a substrate treating apparatus according to some embodiments of the present disclosure. FIG. 8 is an enlarged cross-sectional view of region Z in FIG. 7. FIG. 9 is an enlarged cross-sectional view of region W in FIG. 8. FIG. 10 is a perspective view of a first ground ring according to embodiments of the present disclosure. Since embodiments of FIG. 7 is generally the same as embodiments of FIG. 1, descriptions of the same components will be omitted, and only differences will be described.

Referring to a substrate treating apparatus A in FIGS. 7 through 10, a stage ST may include a chuck EC, a focus ring FR, an edge ring ER, an insulation ring IR, a cover ring CR, a first ground ring GR1, and a second ground ring GR2.

The chuck EC may support a substrate. The chuck EC may fix the substrate at a predetermined position using electrostatic force. That is, the chuck EC may be an electrostatic chuck (ESC). The chuck EC may have a columnar shape centered on a chuck center CA, but is not limited thereto.

The chuck EC may include a puck 5, a plasma electrode 9, a cooling plate 7, and a chuck electrode.

The puck 5 may support the substrate. A burl structure configured to support the substrate may be provided on the upper surface of the puck 5. The puck 5 may include ceramic, but is not limited thereto. Also, a heater may be provided inside the puck 5.

The plasma electrode 9 may be located inside the puck 5. The plasma electrode 9 may be connected to the power source PS in FIG. 6. An electric field may be generated in a process space Ch by power supplied from the power source PS to the plasma electrode 9. To this end, the plasma electrode 9 may include a conductive material.

The cooling plate 7 may be located below the puck 5. The cooling plate 7 may include a material having high thermal conductivity. For example, the cooling plate 7 may include A1. The cooling plate 7 may provide a cooling channel 7h. Cooling water may absorb heat while flowing through the cooling channel 7h.

The chuck electrode may be located inside the puck 5. By the chuck electrode, the substrate on the puck 5 may be fixed to the upper surface of the puck 5.

An insulation plate 41 may be located below the chuck EC. The insulation plate 41 may include an insulating material such as ceramic.

The focus ring FR may surround the chuck EC. Specifically, from a planar perspective, the focus ring FR may surround the substrate placed on the chuck EC. The focus ring FR may be located on the edge ring ER and the insulation ring IR. The focus ring FR may include an insulating material. For example, the focus ring FR may include an insulating material such as quartz.

The edge ring ER may surround the chuck EC. The edge ring ER may be located below the focus ring FR. The edge ring ER may include an insulating material. For example, the edge ring ER may include an insulating material such as quartz.

The insulation ring IR may surround the edge ring ER and the insulation plate 41. The insulation ring IR may be located below the focus ring FR. Also, an inner surface of the insulation ring IR may be in contact with the edge ring ER and the insulation plate 41. Additionally, an outer surface of the insulation ring IR may be in contact with the cover ring CR and the first ground ring GR1. The insulation ring IR may include an insulating material. For example, the insulation ring IR may include an insulating material such as quartz.

The cover ring CR may surround portions of the focus ring FR and the insulation ring IR. Also, the outer surface of the cover ring CR may be surrounded by the plasma baffle PB and the second ground ring GR2. The cover ring CR may include an insulating material such as quartz.

The first ground ring GR1 may be positioned below the cover ring CR. The first ground ring GR1 may include a first region A1, a second region A2, and a third region A3. The first region A1 may have a first outer diameter OR1 with respect to the chuck center CA. The second region A2 may have a second outer diameter OR2 with respect to the chuck center CA. The third region A3 may have a third outer diameter OR3 with respect to the chuck center CA. In some embodiments, the outer diameter of the second region A2 may be the same as the outer diameter of the cover ring CR. That is, the cover ring CR may have the second outer diameter OR2 with respect to the chuck center CA.

The cover ring CR may include a groove on its surface facing the first ground ring GR1. The first region A1 may be received in the groove. That is, the first ground ring GR1 may not directly face the plasma baffle PB due to the presence of the cover ring CR.

The first ground ring GR1 may surround the insulation ring IR. The first ground ring GR1 may be grounded to the process chamber PC in FIG. 7. The first ground ring GR1 may include a conductive material such as A1.

The second ground ring GR2 may be located outside the cover ring CR. Specifically, from a planar perspective, the second ground ring GR2 may surround the outer surface of the cover ring CR. That is, an inner diameter IR1 of the second ground ring GR2 may be greater than or equal to the second outer diameter OR2 of the cover ring CR. In addition, the second ground ring GR2 may be located outside the first ground ring GR1. Additionally, from a planar perspective, the second ground ring GR2 may surround a portion of the first ground ring GR1.

That is, the inner diameter IR1 of the second ground ring GR2 may be greater than or equal to the second outer diameter OR2 of the second region A2 of the first ground ring GR1.

The plasma baffle PB may be located outside the cover ring CR. Specifically, from a planar perspective, the plasma baffle PB may surround a portion of the outer surface of the cover ring CR. Also, the plasma baffle PB may contact an upper surface GR2u of the second ground ring GR2.

The plasma baffle PB may provide a slit PBs. Through the slit PBs, the process space Ch and an exhaust space ES may be connected.

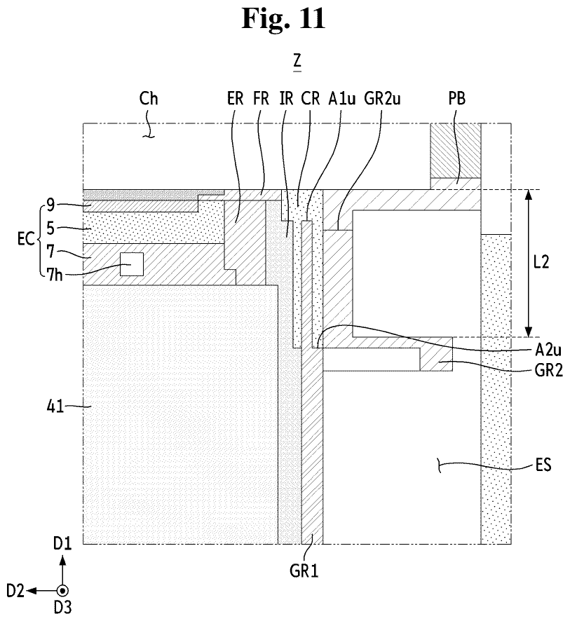

FIG. 11 is an enlarged cross-sectional view of region Z in FIG. 7.

Referring to FIG. 11, the first ground ring GR1 may be positioned below the cover ring CR. The distance between an upper surface A2u of the second region A2 and an upper surface CRu of the cover ring CR may be a second distance L2. For example, the second distance L2 may be 20 mm or more.

In addition, the second ground ring GR2 may be positioned between the plasma baffle PB and the first ground ring GR1 to electrically connect the plasma baffle PB and the first ground ring GR1. That is, the plasma baffle PB may be grounded to the first ground ring GR1 through the second ground ring GR2.

In some embodiments, an upper surface A1u of the first region A1 may be positioned at a higher level than an upper surface GR2u of the second ground ring GR2, but is not limited thereto. Alternatively, the upper surface GR2u of the second ground ring GR2 may be positioned at a higher level than the upper surface A1u of the first region A1.

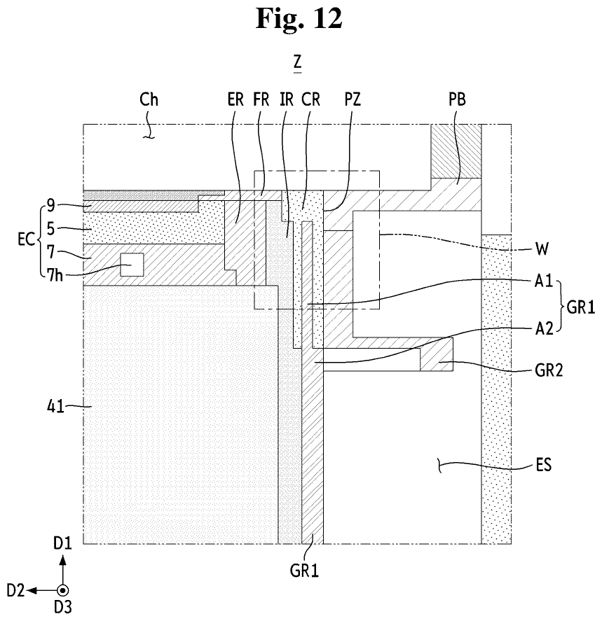

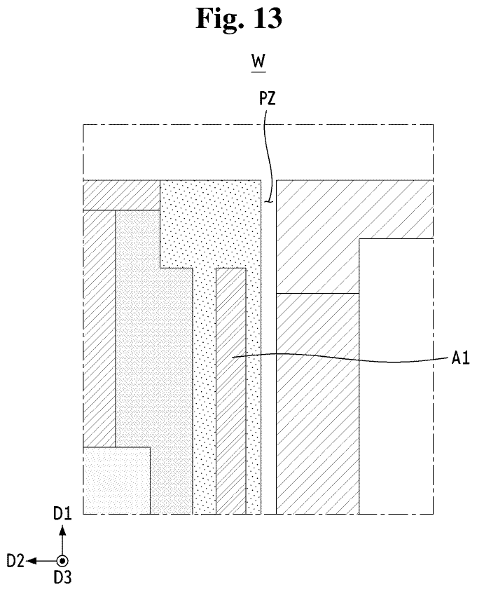

FIG. 12 is an enlarged cross-sectional view of region Z in FIG. 7. FIG. 13 is an enlarged cross-sectional view of region W in FIG. 12.

Referring to FIGS. 12 and 13, the substrate treating apparatus A may include a plasma region PZ between the cover ring CR and the plasma baffle PB, and between the cover ring CR and the second ground ring GR2. The plasma region PZ may refer to a region where plasma in the process space Ch penetrates and is detected.

In some embodiments, the cover ring CR may be positioned between the first region A1 of the first ground ring GR1 and the plasma region PZ. Also, the second region A2 of the first ground ring GR1 may be positioned at a lower level than the plasma region PZ. Accordingly, the first ground ring GR1 may not contact the plasma region PZ.

According to embodiments, the first ground ring GR1 may not directly face the plasma baffle PB due to the presence of the cover ring CR while maintaining an appropriate height of the first ground ring GR1. Accordingly, the first ground ring GR1 may not contact the plasma region PZ and thus may not be exposed to the process gas. That is, peeling of the first ground ring GR1 caused by the process gas may be prevented. Additionally, by preventing the peeling of the first ground ring GR1, it is possible to prevent the material peeled from the first ground ring GR1 (that may include, for example, A1) from reacting with process by-products to form other by-products (for example, AIF), which may fall onto the substrate being processed. Through this, a substrate treating apparatus with improved productivity may be provided.

While embodiments of the present disclosure have been described above with reference to the accompanying drawings, the present disclosure is not limited to the above-described embodiments and may be implemented in various other forms. It will be understood by those skilled in the art that various modifications can be made without departing from the spirit or essential features of the present disclosure. Therefore, the above-described embodiments are to be understood as illustrative in all respects and not limiting.

What is claimed is:

1. A substrate treating apparatus comprising:
a chuck supporting a substrate;
an edge ring surrounding the chuck;
a focus ring positioned on the edge ring;
a cover ring surrounding the edge ring and the focus ring;
a plasma baffle surrounding a side surface of the cover ring;
a first ground ring in contact with a lower surface of the cover ring; and
a second ground ring electrically connected to the first ground ring and in contact with the plasma baffle,
wherein an upper surface of the first ground ring is placed at a level lower than that of an upper surface of the second ground ring.

2. The substrate treating apparatus of claim 1, wherein
a plasma region, into which plasma penetrates from a process space defined by the plasma baffle, is further provided between the cover ring and the plasma baffle and between the cover ring and the second ground ring, and
the first ground ring is positioned at a lower level than that of the plasma region.

3. The substrate treating apparatus of claim 1, wherein an inner diameter of the second ground ring is greater than or equal to an outer diameter of the cover ring.

4. The substrate treating apparatus of claim 3, wherein the second ground ring surrounds an outer surface of the cover ring.

5. The substrate treating apparatus of claim 1, wherein the first ground ring is connected to ground.

6. The substrate treating apparatus of claim 1, wherein the first ground ring includes a first region having a first outer diameter equal to an outer diameter of the cover ring, and a second region having a second outer diameter greater than the first outer diameter.

7. The substrate treating apparatus of claim 6, wherein an inner diameter of the second ground ring is greater than or equal to the first outer diameter.

8. The substrate treating apparatus of claim 1, further comprising:
an insulation ring positioned between the edge ring and the cover ring.

9. The substrate treating apparatus of claim 1, further comprising:
a gas supply unit supplying a process gas for treating the substrate, wherein the process gas includes hydrogen.

10. A substrate treating apparatus comprising:
a chuck supporting a substrate;
an edge ring surrounding the chuck;
a focus ring positioned on the edge ring;
a cover ring surrounding the edge ring and the focus ring;
a plasma baffle surrounding the cover ring;
a first ground ring in contact with the cover ring; and
a second ground ring surrounding the cover ring,
wherein at least a portion of the first ground ring is surrounded by the cover ring.

11. The substrate treating apparatus of claim 10, wherein a plasma region, into which plasma penetrates from a process space defined by the plasma baffle, is further provided between the cover ring and the plasma baffle and between the cover ring and the second ground ring, and
the cover ring is positioned between the plasma region and the first ground ring.

12. The substrate treating apparatus of claim 11, wherein
the first ground ring includes a first region having a first outer diameter, a second region having a second outer diameter greater than the first outer diameter, and a third region having a third outer diameter greater than the second outer diameter, and
the second outer diameter is equal to an outer diameter of the cover ring.

13. The substrate treating apparatus of claim 12, wherein the cover ring includes a groove, in which the first region is received, in a surface facing the first ground ring.

14. The substrate treating apparatus of claim 13, wherein the second region is positioned at a lower level than that of the plasma region.

15. The substrate treating apparatus of claim 13, wherein the upper surface of the first region is positioned at a higher level than that of the upper surface of the second ground ring.

16. The substrate treating apparatus of claim 12, wherein an inner diameter of the second ground ring is greater than or equal to the second outer diameter.

17. The substrate treating apparatus of claim 11, wherein the first ground ring is connected to ground.

18. The substrate treating apparatus of claim 11, further comprising:
an insulation ring positioned between the edge ring and the cover ring.

19. The substrate treating apparatus of claim 11, further comprising:
a gas supply unit supplying a process gas for treating the substrate, wherein the process gas includes hydrogen.

20. A substrate treating apparatus comprising:
a chuck supporting a substrate;
an edge ring surrounding the chuck;
a focus ring positioned on the edge ring;
a cover ring surrounding the edge ring and the focus ring;
an insulation ring positioned between the edge ring and the cover ring;
a plasma baffle surrounding a side surface of the cover ring;
a first ground ring in contact with a lower surface of the cover ring and connected to ground; and
a second ground ring electrically connected to the first ground ring and in contact with the plasma baffle,
wherein
an upper surface of the first ground ring is positioned at a lower level than that of an upper surface of the second ground ring,
a plasma region, into which plasma penetrates from a process space defined by the plasma baffle, is further provided between the cover ring and the plasma baffle and between the cover ring and the second ground ring, and
the first ground ring is positioned at a lower level than that of the plasma region.
